(19) United States
(12) Patent Application Publication
(10) Pub. No.: US 2001/0022387 A1
(43) Pub. Date: Sep. 20, 2001

(54) Pattern forming method for semiconductor manufacturing

(76) Inventors: Naoki Sano, Kanagawa (JP); Toshiyuki Sameshima, Kanagawa (JP); Masaki Hara, Kanagawa (JP); Setsuo Usui, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/858,756

(22) Filed: May 16, 2001

Related U.S. Application Data
(62) Division of application No. 08/264,259, filed on Jun. 21, 1994, now abandoned.

(30) Foreign Application Priority Data
May 2, 1991 (JP) P100805/91

(51) Int. Cl. H01L 29/06

(52) U.S. Cl. 257/622

(57) ABSTRACT

A process for pattern forming during semiconductor manufacturing comprises the steps of forming a resist pattern on a substrate, then a metallic layer, of aluminum for example, is applied to the complete surface of the substrate and the resist pattern, by spattering or the like. Next a heating step is carried out. The heating step is accomplished by immersing the resist pattern in a solvent heated in the vicinity of a boiling point thereof, for effecting expansion of the resist pattern. Then the resist pattern is removed along with undesired remnants of the metallic layer which are adhered to the resist pattern.

### BACKGROUND OF THE INVENTION

1. Field of the Invention

The present invention relates generally to a method for use in manufacturing semiconductors. Particularly, the present invention relates to a method of patterning semiconductor layers during the manufacturing process.

2. Description of the Prior Art

A conventional liftoff patterning process for semiconductors is explained with reference to FIGS. 17-19. As shown in FIG. 17, an undercut resist pattern layer 2 is applied over a substrate 1. Next, a membrane of a metallic material 3 is applied over the substrate and resist pattern layer by spattering, or the like (FIG. 18) in proportion to an amount needed for the type of device being made. Also, rather than a metal layer, a layer of conductive, insulative or other material may alternatively be applied.

Then, the resist layer is dissolved by a solvent or the like to be removed from the surface of the substrate. At this time, parts of the metallic layer 3 atop the resist layer are also removed leaving a layer of metallic membrane 3 adhered to the substrate 1 at parts of the surface which were not covered with the resist layer 2 (FIG. 19).

Nevertheless, according to the above described undercut resist method, the layer of metallic membrane 3 and undesired portions of the metallic membrane 3 adhered to the resist layer 2, may not separate cleanly when the resist is removed, resulting in remnants of the metallic layer which have separated from the resist adhering to the substrate (FIG. 19) which may require extra processing steps for removal or, if not removed, may cause misoperation of the completed device.

To solve this problem, Japanese Patent Application First Publication 1-19256 discloses a method in which the substrate is exposed an ultra sonic wave is oscillated between 80 KH_{Z}-200 KH_{Z} for destroying the unwanted remnants of the metallic membrane. However, in case of using this procedure, the workpiece must be exposed to a preliminary wave of 20 KH_{Z}-50 KH_{Z} or, dipped in a solvent or blend of solvents to facilitate expansion, or swelling of the resist.

### SUMMARY OF THE INVENTION

It is therefore a principal object of the present invention to provide a method for patterning a substrate which overcomes the drawbacks of the prior art.

It is a further object of the present invention to provide a pattern forming method for semiconductor manufacturing which may accomplish efficient removal of undesired portions of layers of material applied during semiconductor manufacture.

In order to accomplish the aforementioned and other objects, a method for pattern forming during semiconductor manufacture comprises the steps of: forming a resist pattern of a heat expandable material on a substrate; covering the surface of the substrate, including the resist pattern with a layer of a desired material; immersing the resist pattern in a solvent heated in the vicinity of a boiling point thereof; and removing the resist pattern and undesired remnants of the layer of a desired material.

According to another aspect of the present invention, a method of forming transparent electrodes is disclosed, comprising the steps of: applying a layer of transparent insulating material to a substrate; applying a resist layer over the transparent insulating material in a predetermined pattern; removing portions of the transparent insulating material exposed through the pattern formed in the resist layer; applying a layer of iridium tin oxide over the resist layer and a channel formed by the removal of the portions of the transparent insulating material; immersing the resist layer in a solvent heated in the vicinity of a boiling point thereof; and removing the resist layer and undesired portions of the iridium tin oxide.

According to a still further aspect of the present invention, a method of forming thin film transistors is provided, comprising the steps of: applying a layer of a first semiconductive material over a substrate; applying a resist layer in a predetermined pattern over the first semiconductive material; removing portions of the first semiconductive material exposed through the pattern formed in the resist layer; applying a layer of a first conductive material over the resist layer and a channel formed by the removal of the portions of the first semiconductive layer; immersing the resist layer in a solvent heated in the vicinity of a boiling point thereof; removing the resist layer and undesired portions of the first conductive material applying a layer of insulating material over a surface of the first semiconductive material and the first conductive material; applying a layer of positive photo-resist over the insulating material; irradiating the substrate from a side opposite that to which the layer of the first semiconductive material has been applied; applying a layer of a second semiconductive material over the insulating material and portions of the positive photo-resist remaining after the irradiation; immersing the positive photo resist layer in a solvent heated in the vicinity of a boiling point thereof; removing the positive photo resist and undesired portions of the second semiconductive material; applying a second resist layer over the second semiconductive material so as to mask the second semiconductive material from a channel formed in the second semiconductive material by removal of the positive photo resist; applying a layer of a semiconductive material other than the second semiconductive material over the second resist layer and portions of the insulating layer exposed by removal or the positive photo resist; immersing the second resist layer in a solvent heated in the vicinity of a boiling point thereof; and removing the second resist layer and undesired portions of the semiconductive material other than the second semiconductive material.

### BRIEF DESCRIPTION OF THE DRAWINGS

In the drawings:

FIG. 1 is an initial cross sectional view of a pattern forming process of a first embodiment according to the invention;

FIG. 2 is a cross sectional view during the process of the first embodiment;

FIG. 3 is a cross sectional view of the result of the process of the first embodiment;

FIG. 4 is a preliminary cross sectional view of a pattern forming process of a second embodiment according to the invention;

FIG. 5 is a cross sectional view during the process of the second embodiment;

FIG. 6 is a further cross sectional view during the process of the second embodiment;

FIG. 7 is a cross sectional view of the result of the process of the second embodiment;

FIG. 8 is an initial cross sectional view of a pattern forming process according to a third embodiment of the invention;

FIG. 9 is a second cross sectional view of a stage of the process of the third embodiment;

FIG. 10 is a third cross sectional view of another stage of the process of the third embodiment;

FIG. 11 is a fourth cross sectional view of another stage in the process of the third embodiment;

FIG. 12 is a fifth cross sectional view of another stage in the process of the third embodiment;

FIG. 13 is a final cross sectional view of the process of the third embodiment;

FIG. 14 shows a cross sectional view of a first application of the process of the invention;

FIG. 15 shows a cross sectional view of a second application of the process of the invention;

FIG. 16 shows a cross sectional view of a third application of the process of the invention;

FIG. 17 shows an initial view of the pattern forming process according to the prior art;

FIG. 18 shows view of a subsequent stage in the pattern forming process of the process of FIG. 17;

FIG. 19 shows a view of another stage in the process of FIGS. 17 and 18.

### DESCRIPTION OF THE PREFERRED EMBODIMENT

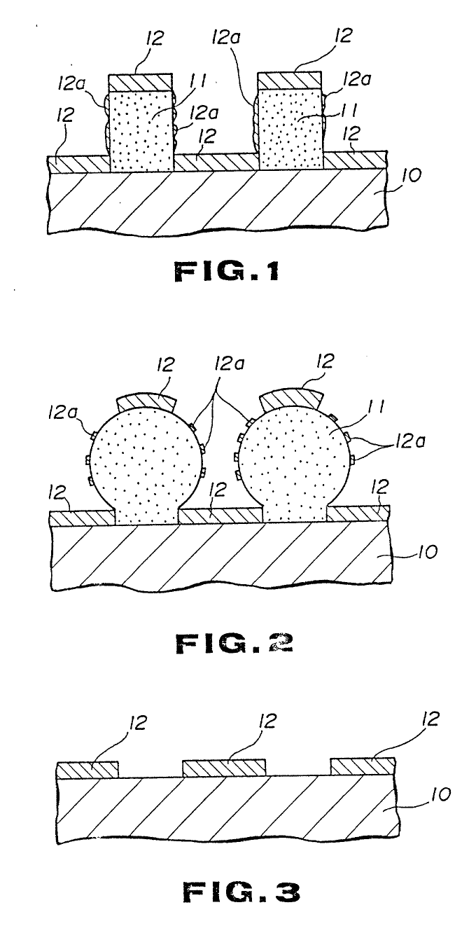

Referring now to the drawings, a method of forming patterns on a substrate according to a first embodiment of the invention will be explained with reference to FIGS. 1-3. First a resist pattern 11 is applied to an insulated substrate layer 10 on one surface thereof and, subsequently, a metallic membrane layer 12 is applied to the entire surface over the resist pattern 11. The membrane layer 12 may be aluminum and applied by spattering, for example (FIG. 1). When the aluminum membrane layer 12 is applied over the resist pattern 11, a certain amount of undesired aluminum material will adhere to the resist pattern 11.

Next, the resist pattern is dipped in a solvent such as water which is heated close to the boiling point (100° C.). According to this heating process, swelling of the resist pattern 11 to its full capacity is promoted, as shown in FIG. 2. Further, the above-mentioned heating step removes undesired remnants 12a of the metallic (aluminum) membrane 12 which adhere to the resist pattern 11. As the pressure of gas (i.e. N2) formed in the resist pattern 11 during swelling thereof becomes high according to this process, the unwanted portions of the metallic layer 12a are stretched thin and removal thereof is facilitated.

Next, the resist pattern 11 is removed by a solvent leaving the patterned aluminum layer on the substrate without undesired remnants.

It will be noted that the above method can be used to facilitate formation of both positive and negative topographies for semiconductor devices.

Further, according to the above method, liftoff effect is enhanced and ultra-sonic cleaning of the workpiece may be effected at frequencies of less than 80 KH_{Z}.

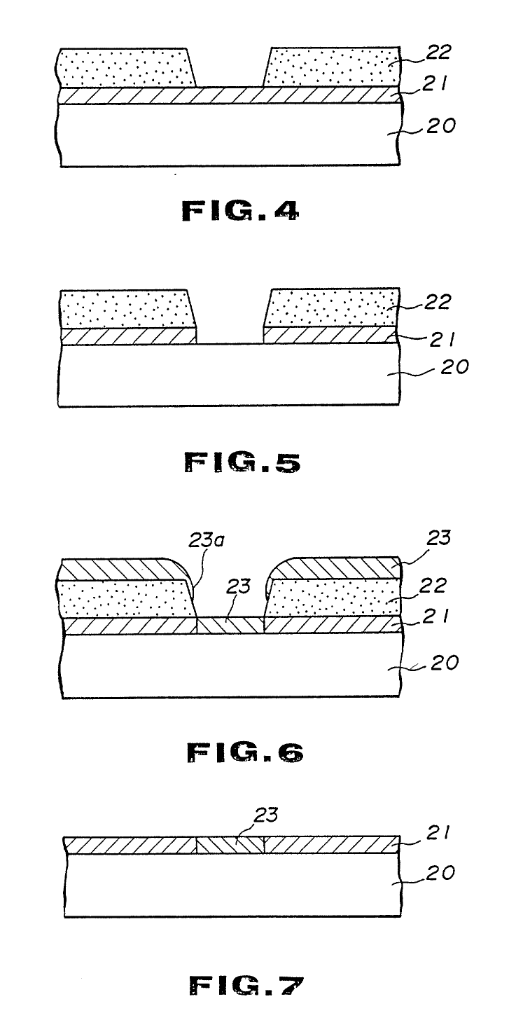

Hereinbelow, a second embodiment of the invention will be described with reference to FIGS. 4-7.

The second embodiment of the invention is applicable to such process as forming ITO transparent electrodes (Indium Tin Oxide) patterning for LCD manufacture, transparent touch sensors or the like.

According to the second embodiment, referring to FIG. 4, a glass substrate 20 is coated with a layer of transparent insulating layer 21 such as Silicon Nitride (SiNx), for example. Then, a resist layer 22 is applied over the insulating layer 21, the resist layer may formed by a photo resist technique, for example.

Next, referring to FIG. 5, the resist layer 22 acts as a mask while the SiNx layer 21 is patterned by etching, for example. After the etching step, an ITO layer 23 is applied by spattering or the like. As seen in FIG. 6 the ITO layer may include undesired portions 23a. After this step the procedure is carried out substantially same as in the previous embodiment, that is, the workpiece is immersed in water heated close to the boiling point to expand the resist layer and facilitate removal thereof along with the unwanted portions of the ITO layer 23 resulting in a finished product as shown in FIG. 7.

By the above process, unwanted material can be suitably removed and uniformly flat surface characteristics may be obtained.

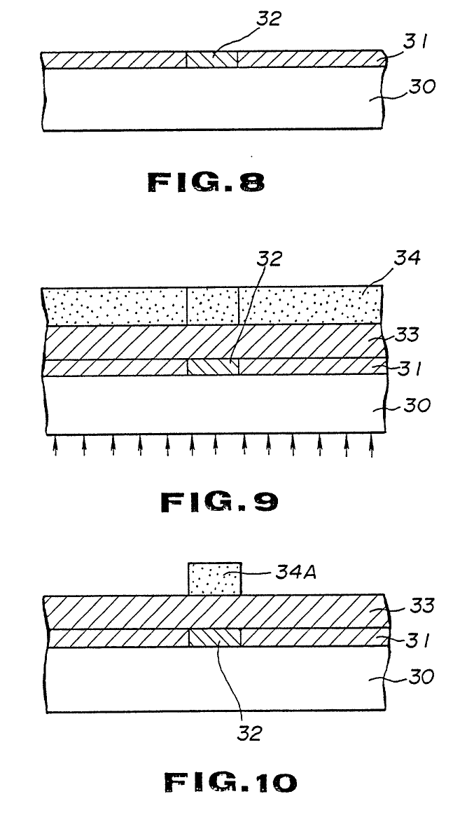

Referring to FIGS. 8-13, the third embodiment of the invention will be explained hereinbelow.

The third embodiment is drawn to forming bottom gate type TFT (Thin Film Transistor) arrangements for liquid crystal display elements. According to this embodiment, a Silicon Nitride layer 31 is applied over a glass substrate 30. Then, via the same process as the above-described second embodiment, a gate electrode 32 is formed of chromium (Cr) or the like (see FIG. 8). According to the process of the second embodiment, the gate electrode 32 is thus provided in the etched portion of the SiNx layer with flat surface characteristics therebetween. Then, referring to FIG. 9, a insulating layer 33 is applied over the SiNx layer including the gate electrode 32 and, a positive photo-resist layer 34 is applied over the insulating layer 33. The above construction is then irradiated (exposed) from underneath, that is through the glass substrate 30 while the gate electrode 32 acts as a mask for the positive photo-resist 34. After exposure, a resist pattern 34A is formed on the insulating layer 33, as seen in FIG. 10.

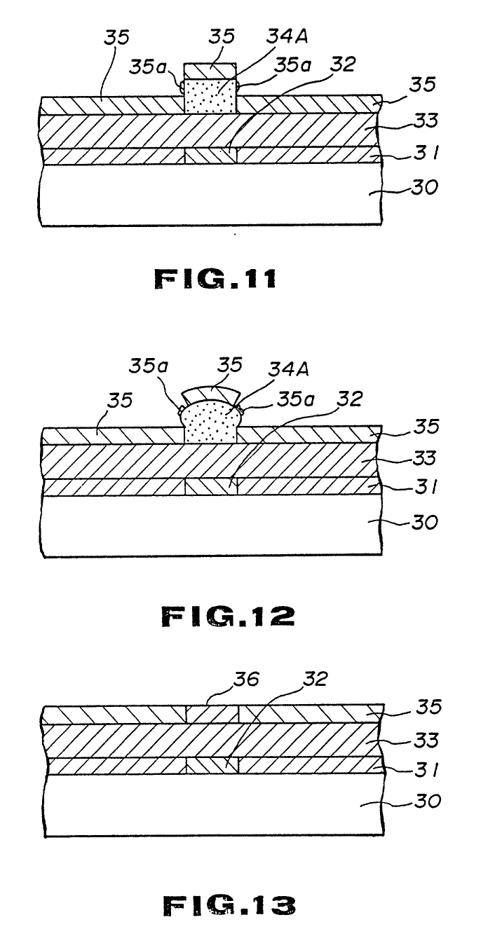

Then, referring to FIG. 11 an n type (or alternatively p type) amorphous silicon (a-Si) layer is 35 is formed over the insulating layer 33 and the resist pattern 34A. According to the application of the a-Si layer, remnant portions 35a adhere to the sides of the resist pattern 34A.

Then, similarly to the previous embodiments, the resist layer is immersed in a solvent (water) heated to near boiling (100° C.) for promoting expansion of the resist layer 34A (FIG. 12) for effecting efficient and complete removal of the unwanted remnant portions 35a of lo the a-Si layer 35.

Referring to FIG. 13, after the above process, the process of the second embodiment, used for forming the ITO layer, may be carried out for forming a silicon channel, or pattern, 36 in the space created by removal of the resist layer 34A. The silicon pattern 36 may be of a-Si for example for treatment by laser, etc. for activation or crystallization of the silicon layer 36.

Further, although, in the above-described embodiments, water is used as a solvent, the present invention may also be preferably implemented using alcohol, such as isopropyl alcohol or ethanol, for example, as a solvent. Also, liquid nitrogen may also be utilized. In addition, rather than immersing the resist pattern in the solvent, the method of the invention is effective if the resist pattern is merely exposed to the heated solvent, as in steaming, for example, rather than fully immersing the resist pattern. Also, is the speed of heating of the solvent is raised, a pressure difference arising in the resist pattern and the undesired portions a layer to be removed are increased and the overall effect of the process is heightened. That is, the speed and efficiency of the removal of undesired portions is enhanced.

Further, by appropriate selection of the wavelength of light used for photolysis and/or through use of a transparent substrate and/or if irradiation is applied to the immersed side of the construction the liftoff effect may be further enhanced.

Furthermore, if a liquid used as a resist rinse is heated to a high temperature a resist heating step and a resist rinse step may be combined.

In addition, in the first embodiment, although water may be used as a solvent for deposition of the aluminum layer, alcohol based solvents are preferably employed.

The present invention however, is not limited to the applications presented in the previous examples however, but may be preferably applied to a wide range of other applications as well.

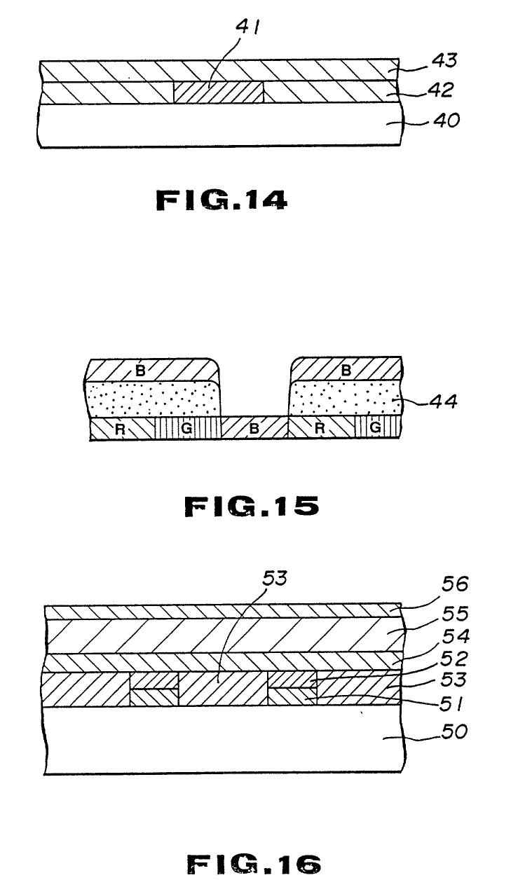

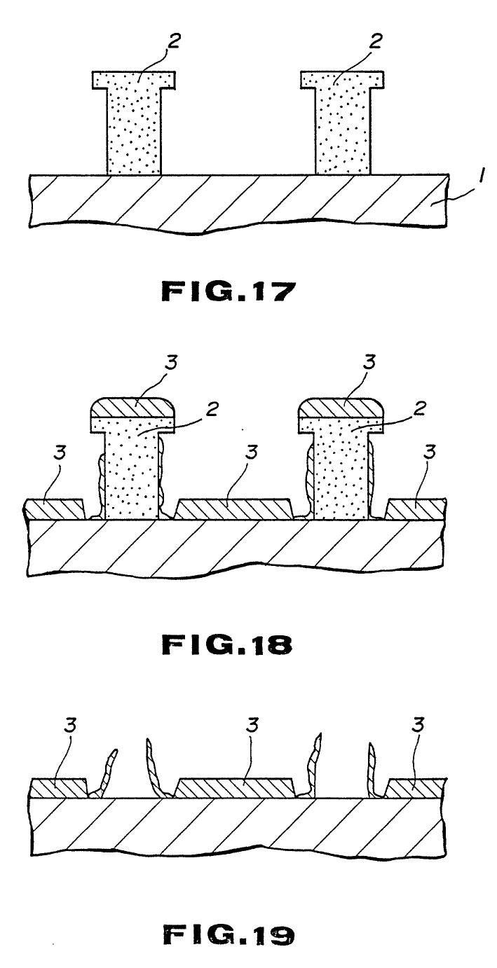

For example, referring to FIG. 14, in preparing LCD display elements, a black matrix portion 41 is applied above a glass substrate 40 according to the process of the invention. Thus, high contrast characteristics are assured as well as flat surface characteristics. Layers 42, and 43 in FIG. 14 are insulation layers.

FIG. 15 shows the process of the present invention as applied to the manufacture of color filters. Numeral 44 indicates a resist layer which is utilized to form the color elements of the filter in the same way as formation of the black matrix portion of the above embodiment.

FIG. 16 shows the process of the invention as applied to forming thin-film transistors. As seen in the drawing, in ITO layer 51 is applied to a glass substrate 50. A doping layer 52 is applied over the ITO layer and the layers 51 and 52 are held between an insulating layer 53. Above this, an a-Si layer 54 is applied, and then another insulating layer 55 and finally a gate wiring layer 56, of aluminum for example, is applied. According to the provision of the ITO layer 51 and the doping layer 52, the gate wiring layer may be provided with desirably flat surface characteristics.

Thus, according to the present invention, highly desirably positive resist characteristics may be obtained, further, reverse taper and/or undercut resist formations are not necessary according to the process of the invention. Thus the process-is simplified compared to conventional methods. Also, due to the above, patterning accuracy for large scale, submicron arrangements may be improved.

The process of the invention may also be employed for patterning of polymers and the like.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A method of forming patterns during semiconductor manufacture, comprising the steps of:
forming a resist pattern of a heat expandable material on a substrate;
covering the surface of said substrate, including said resist pattern with a layer of a desired material;
immersing said resist pattern in a solvent heated in the vicinity of a boiling point thereof; and
removing said resist pattern and undesired remnants of said layer of a desired material.

2. A method as set forth in claim 1, wherein said solvent is water heated in the vicinity of 100° C.

3. A method as set forth in claim 1, wherein said solvent is alcohol.

4. A method as set forth in claim 1, wherein said solvent is isopropyl alcohol.

5. A method as set forth in claim 1, wherein said solvent is ethanol.

6. A method as set forth in claim 1, wherein said solvent is liquid nitrogen.

7. A method as set forth in claim 1, wherein said desired material is aluminum.

8. A method as set forth in claim 1, wherein said layer of a desired material is applied by spattering.

9. A method as set forth in claim 1, further including the step of rinsing said resist pattern after said immersing step.

10. A method as set forth in claim 1, further including a cleaning step.

11. A method as set forth in claim 10, wherein said cleaning step is accomplished by ultrasonic cleaning.

12. A method as set forth in claim 11, wherein said ultrasonic cleaning step is carried out a frequencies less than 80 KH_{Z}.

13. A method as set forth in claim 1, wherein said immersing step is followed by a rinsing step.

14. A method as set forth in claim 1, wherein said immersing step is combined with a rinsing step.

15. A method as set forth in claim 1, wherein a steaming step, wherein said resist layer is exposed in the vicinity of said solvent heated to a boiling point thereof is substituted for said immersing step.

16. The product of the process of claim 1.

17. A method of forming transparent electrodes comprising the steps of:
applying a layer of transparent insulating material to a substrate;
applying a resist layer over said transparent insulating material in a predetermined pattern;
removing portions of said transparent insulating material exposed through said pattern formed in said resist layer;
applying a layer of indium tin oxide over said resist layer and a channel formed by said removal of said portions of said transparent insulating material;
immersing said resist layer in a solvent heated in the vicinity of a boiling point thereof;
removing said resist layer and undesired portions of said indium tin oxide.

18. A method as set forth in claim 17, wherein said transparent insulating material is silicon nitride.

19. A method according to claim 17, wherein said solvent is water heated in the vicinity of 100° C.

20. A method as set forth in claim 17, wherein said solvent is alcohol.

21. A method as set forth in claim 17, wherein said solvent is isopropyl alcohol.

22. A method as set forth in claim 17, wherein said solvent is ethanol.

23. A method as set forth in claim 17, wherein said solvent is liquid nitrogen.

24. A method as set forth in claim 17, wherein said substrate is glass.

25. A method as set forth in claim 17, wherein said indium tin oxide is applied by spattering.

26. A method as set forth in claim 17, wherein said further including the step of rinsing said resist pattern.

27. A method as set forth in claim 17, wherein said further including a cleaning step after said removal step.

28. A method as set forth in claim 27, wherein said cleaning step is accomplished by ultrasonic cleaning.

29. A method as set forth in claim 28, wherein said ultrasonic cleaning step is carried out a frequencies less than 80 KH_{Z}.

30. A method as set forth in claim 17, wherein said immersing step is followed by a rinsing step.

31. A method as set forth in claim 17, wherein said immersing step is combined with a rinsing step.

32. A method as set forth in claim 17, wherein a steaming step, wherein said resist layer is exposed in the vicinity of said solvent heated to a boiling point thereof is substituted for said immersing step.

33. The product of the process of claim 17.

34. A method of forming thin film transistors comprising the steps of:
applying a layer of a first semiconductive material over a substrate;
applying a resist layer in a predetermined pattern over said first semiconductive material;
removing portions of said first semiconductive material exposed through said pattern formed in said resist layer;
applying a layer of a first conductive material over said resist layer and a channel formed by said removal of said portions of said first semiconductive layer;
immersing said resist layer in a solvent heated in the vicinity of a boiling point thereof;
removing said resist layer and undesired portions of said first conductive material;
applying a layer of insulating material over a surface of said first semiconductive material and said first conductive material;
applying a layer of positive photo-resist over said insulating material;
irradiating said substrate from a side opposite that to which the layer of said first semiconductive material has been applied;
applying a layer of a second semiconductive material over said insulating material and portions of said positive photo-resist remaining after said irradiation;
immersing said positive photo resist layer in a solvent heated in the vicinity of a boiling point thereof;
removing said positive photo resist and undesired portions of said second semiconductive material;
applying a second resist layer over said second semiconductive material so as to mask said second semiconductive material from a channel formed in said second semiconductive material by removal of said positive photo resist;
applying a layer of a semiconductive material other than said second semiconductive material over said second resist layer and portions of said insulating layer exposed by removal or said positive photo resist;
immersing said second resist layer in a solvent heated in the vicinity of a boiling point thereof; and
removing said second resist layer and undesired portions of said semiconductive material other than said second semiconductive material.

35. A method as set forth in claim 34, wherein said substrate is glass.

36. A method as set forth in claim 34, wherein a step of applying first and second materials is substituted for said step of applying said first conductive material.

37. A method as set forth in claim 34, wherein said first semiconductive material is silicon nitride.

38. A method as set forth in claim 34, wherein said first conductive material is chromium.

39. A method as set forth in claim 34, wherein said second semiconductive material is p-type or n-type amorphous silicon.

40. A method as set forth in claim 34, wherein said semiconductive material other than said second semiconductive material is silicon.

41. A method as set forth in claim 34, wherein each of said immersing steps is followed by a rinsing step.

42. A method as set forth in claim 34, wherein said each of said immersing steps is combined with a rinsing step.

43. A method as set forth in claim 34, wherein a steaming step, wherein said resist layer is exposed in the vicinity of said solvent heated to a boiling point thereof is substituted for each, or any one of, said immersing steps.

44. A method as set forth in claim 34, further including a step of crystallizing said semiconductive material other than said second semiconductive material.

45. A method as set forth in claim 44, wherein said crystallization is effected by laser processing.

46. A method as set forth in claim 34, further including the step of activating said semiconductive material other than said second semiconductive material.

47. A method as set forth in claim 46, wherein said activation is effected by laser processing.

48. A method according to claim 34, wherein said solvent is water heated in the vicinity of 100° C.

49. A method as set forth in claim 34, wherein said solvent is alcohol.

50. A method as set forth in claim 34, wherein said solvent is isopropyl alcohol.

51. A method as set forth in claim 34, wherein said solvent is ethanol.

52. A method as set forth in claim 34, wherein said solvent is liquid nitrogen.

53. A method as set forth in claim 34, further including the step of rinsing said resist pattern after each immersing step.

54. A method as set forth in claim 34, further including a cleaning step.

55. A method as set forth in claim 54, wherein said cleaning step is accomplished by ultrasonic cleaning.

56. A method as set forth in claim 55, wherein said ultrasonic cleaning step is carried out a frequencies less than 80 KH_{Z}.

57. The product of the process of claim 34.
